(19) United States
(12) Patent Application Publication
(10) Pub. No.: US 2007/0048980 A1
(43) Pub. Date: Mar. 1, 2007

(54) METHOD FOR POST-RIE PASSIVATION OF SEMICONDUCTOR SURFACES FOR EPITAXIAL GROWTH

(75) Inventors: Judson R. Holt, Wappingers Falls, NY (US); Siddhartha Panda, Beacon, NY (US)

Correspondence Address: CANTOR COLBURN LLP - IBM FISHKILL, 55 GRIFFIN ROAD SOUTH, BLOOMFIELD, CT, 06002, US

(73) Assignee: INTERNATIONAL BUSINESS MACHINES CORPORATION, Armonk, NY (US)

(21) Appl. No.: 11/161,964

(22) Filed: Aug. 24, 2005

(51) Int. Cl. H01L 21/20; H01L 21/302

(52) U.S. Cl. 438/504; 438/712; 438/714; 257/E21.09

(57) ABSTRACT

A method for preparing a substrate for epitaxial crystal growth thereon includes performing a reactive ion etch (RIE) on a selected area of the substrate to be prepared for epitaxial crystal growth, discontinuing the introduction of an etchant species associated with the RIE, and introducing a monolayer forming species into a chamber containing the substrate. The neutral species is selected so as to form a passivating monolayer on the selected area of the substrate, wherein the monolayer is resistant to the formation of native oxide thereon.

### BACKGROUND

The present invention relates generally to semiconductor device processing techniques, and, more particularly, to a method for post-RIE (reactive ion etch) passivation of semiconductor surfaces in preparation for epitaxial growth thereon.

In the realm of semiconductor manufacturing, reactive ion etching (RIE) and epitaxial layer growth are common processes used in forming various types of semiconductor devices. For example, in CMOS device manufacturing, there has recently been introduced certain performance enhancing techniques such as “hybrid orientation technology” (HOT), in which n-type devices are manufactured on silicon of a first crystalline orientation and p-type devices are manufactured on silicon of a second crystalline orientation in order to maximize the carrier mobility of both the n-type and p-type devices. In addition, strained silicon (e.g., devices with a SiGe replacement source/drain region) is another technique that has been used to enhance carrier mobility and increase the switching speed of high-performance CMOS circuits.

Prior to the epitaxial growth step, a pre-clean sequence is typically used, which concludes with an etch (e.g., aqueous hydrofluoric acid (HF)) to remove the oxide layer on the portion of the substrate targeted for the epitaxial growth. This etch step is necessary since epitaxial growth can only occur on a bare crystal surface. While a certain amount of residual interfacial oxygen is acceptable for epitaxial growth, this value is typically much less than one monolayer (ML). If the surface oxygen content is high enough, it will detrimentally affect the growth of the epitaxial layer by nucleating defects or completely blocking the growth.

However, one side effect associated with the conventional HF pre-clean results from the fact that the HF etch rate of a deposited oxide is much higher than that of the native oxide. Thus, where deposited oxide structures are present (e.g., shallow trench isolations, sidewall spacers), such structures may suffer significant erosion from the HF pre-clean. Moreover, even after the HF pre-clean, there is typically some queue time in which a native oxide begins to re-grow on the surface. In order to remove such additional native oxide, a subsequent clean step such as a hydrogen pre-bake step may also be used. Unfortunately, this additional step is also disadvantageous in that a hydrogen bake can significantly increase the thermal budget of the epitaxial process.

Accordingly, in such types of applications where an epitaxial growth layer (e.g., Si or SiGe) is formed subsequent to an RIE step, it would be desirable to be able to prepare a semiconductor surface for epitaxial growth following RIE in a manner that overcomes the disadvantages associated with HF etching and hydrogen baking.

### SUMMARY

The above discussed drawbacks and deficiencies of the prior art are overcome or alleviated by a method for preparing a substrate for epitaxial crystal growth thereon. In an exemplary embodiment, the method includes performing a reactive ion etch (RIE) on a selected area of the substrate to be prepared for epitaxial crystal growth, discontinuing the introduction of an etchant species associated with the RIE, and introducing a monolayer forming species into a chamber containing the substrate. The monolayer forming species is selected so as to form a passivating monolayer on the selected area of the substrate, wherein the monolayer is resistant to the formation of native oxide thereon.

In another embodiment, a method for forming a semiconductor device layer includes performing a reactive ion etch (RIE) on a selected area of a semiconductor substrate, discontinuing the introduction of an etchant species associated with the RIE, and introducing a monolayer forming species into a chamber containing the substrate. The monolayer forming species is selected so as to form a passivating monolayer on the selected area of the substrate, said monolayer being resistant to the formation of native oxide thereon. An epitaxially grown layer is then formed on the monolayer.

### BRIEF DESCRIPTION OF THE DRAWINGS

Referring to the exemplary drawings wherein like elements are numbered alike in the several Figures:

FIG. 1 is a schematic diagram of an exemplary RIE apparatus suitable for use in accordance with an embodiment of the invention;

FIG. 2 is a process flow diagram illustrating a conventional method of preparing a wafer substrate for epitaxial crystal growth on selective locations, using an aqueous HF precleaning operation; and

FIG. 3 illustrates a process flow diagram illustrating a method for preparing a substrate for epitaxial crystal growth thereon by forming a post-RIE passivating monolayer, in accordance with an embodiment of the invention.

### DETAILED DESCRIPTION

Disclosed herein is a method for post-RIE passivation of semiconductor surfaces in preparation for epitaxial growth thereon. Briefly stated, a passivating monolayer (such as fluorine, for example) is formed on a semiconductor surface post-RIE and in preparation for epitaxial layer growth thereon. In particular, by altering a conventional RIE process to introduce (for example) neutral molecular fluorine into the processing chamber once the plasma source is turned off, a self-limiting fluorine monolayer may be formed that is stable and controls the native oxide formation thereon. This in turn eliminates the need for a separate pre-clean step altogether, and the queue time window may be correspondingly increased or even eliminated.

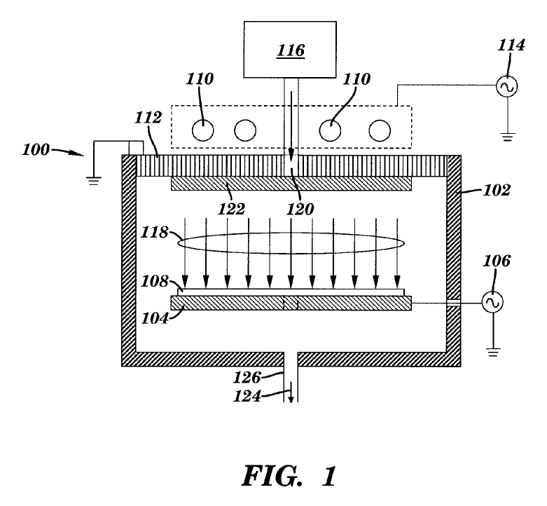

Referring initially to FIG. 1, there is shown a simplified schematic diagram of an exemplary RIE apparatus 100 suitable for use in accordance with an embodiment of the invention. The apparatus 100 includes a wafer chamber 102 having an electrode 104 therein. The electrode 104 is coupled to a first RF source 106 and retains a semiconductor wafer 108 thereon. A set of induction coils 110 is placed over an RF dielectric window 112 disposed atop the chamber 102, with the coils 110 being coupled to a second RF source 114. A chemical gas source 116 used in the generation of a reactive plasma species (indicated by arrows 118) that bombards the wafer 108 is introduced into the chamber 102 through inlets 120 and the showerhead 122. The bombarding ions react with the exposed material on the wafer 108 to be etched to produce highly volatile reaction byproducts 124 that are pumped out of the chamber 102 through an exhaust port 126.

Although the above described apparatus illustrates an inductively coupled RIE reactor, it will be appreciated that a capacitively coupled RIE could also be used. Moreover, a pure chemical etch apparatus (i.e., no sputtering component) could be used wherein a single RF source is provided for plasma creation only.

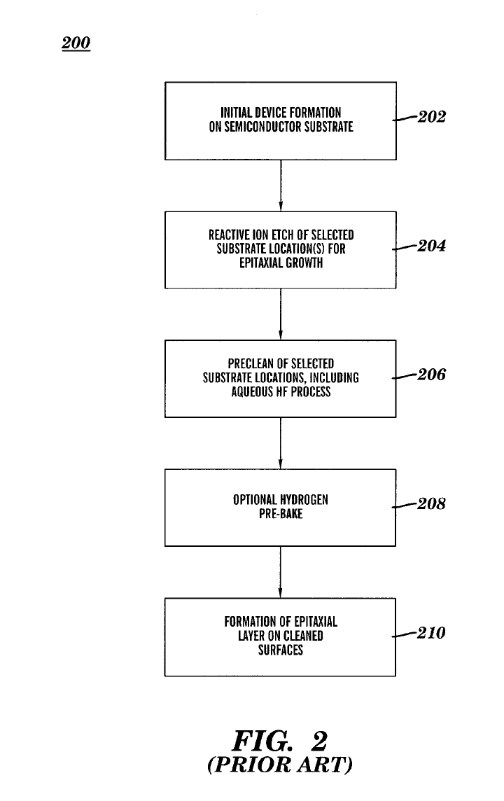

Referring now to FIG. 2, there is shown a process flow diagram illustrating a conventional method 200 of preparing a wafer substrate for epitaxial crystal growth on selective locations. In block 202, a semiconductor substrate is initially prepared in accordance with appropriate processes of record, depending on the type of devices to be formed. For example, in CMOS processing, shallow trench isolation (STI) areas may be formed on the substrate, or perhaps FET devices of one polarity type are formed in a silicon substrate of a first crystalline orientation, such as may be the case for hybrid orientation technology (HOT) devices discussed above. Alternatively, certain areas of a silicon-germanium substrate may be patterned for selective silicon growth thereon. Regardless of the particular application, a desired area for subsequent epitaxial crystal growth is patterned.

In block 204, the wafer is subjected to a reactive ion etching in order to remove material (e.g., oxides, nitrides, silicon) and expose a substrate surface for selective epitaxial growth thereon. The RIE may be carried out, for example, using the general type of apparatus 100 shown in FIG. 1. As also indicated previously, following the completion of the RIE, a wafer is conventionally subjected to a precleaning process to rid the etched substrate surfaces of oxides that typically form when the bare crystal surface is exposed to oxygen or moisture. Such exposure occurs, for example, when moving substrates between processing chambers at atmospheric conditions, when a small amount of oxygen or moisture remaining in a vacuum chamber contacts the wafer/film layer, or when a layer is contaminated by the etching itself. In addition, other contaminants may include sputtered material from an oxide over-etch, residual photoresist from a stripping process, leftover hydrocarbon or fluorinated hydrocarbon polymers from a previous oxide etch step, or redeposited material from a previous preclean sputter etch process.

Thus, as illustrated in block 206, a preclean sequence is used to prepare the newly etched substrate surfaces for epitaxial growth. The preclean sequence may begin, for example, with wet cleaning the substrate surface using an RCA clean (as is known to one skilled in the art) containing hydrogen peroxide (H₂O₂). In addition, to remove native oxide from the substrate (e.g., silicon) surface, an immersion in HF solution or treatment by an HF vapor is used. The HF cleaned surface is then rinsed in de-ionized water and dried to initially result in a substantially hydrophobic oxide free surface by passivating the surface with Si—H bonds.

However, due to practical queue-related time constraints, the clean surface will begin to re-oxidize and, as such, an optional hydrogen pre-bake operation is implemented as shown in block 208. This may be implemented, for example, in the same chamber used for the epitaxy deposition or, alternatively, in a separate baking chamber. The hydrogen pre-bake process is intended to remove residual oxide from the substrate surface prior to the epitaxy deposition. Finally, as shown in block 210, the selected substrate areas (having undergone an HF etch and optional hydrogen pre-bake), have the desired epitaxial layer formed thereon.

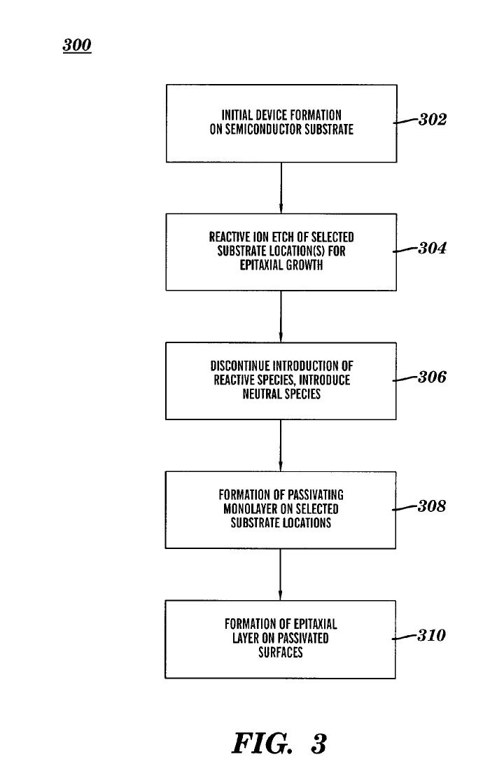

In contrast, FIG. 3 is a process flow diagram illustrating a method 300 for preparing a substrate for epitaxial crystal growth, in accordance with an embodiment of the invention. As was the case in FIG. 2, a semiconductor substrate is initially prepared in accordance with appropriate processes of record, depending on the type of devices to be formed, illustrated in block 302. In block 304, the selected areas of the substrate for epitaxial growth are subjected to RIE. However, in lieu of an aqueous HF preclean, the conventional RIE process is adjusted to form a passivating monolayer on the newly etched substrate surfaces.

More specifically, as illustrated in block 306, the source of the reactive plasma (etchant) species is removed once the RIE endpoint is reached. For example, this may be implemented by deactivating the plasma source of the reactive species (i.e., the second RF excitation source 114 in contact with the induction coils of the RIE apparatus 100 of FIG. 1). Instead of a plasma-based reactive gas species 118 being produced within the RIE chamber, a monolayer forming (e.g., neutral) species is instead introduced. The result of such neutral species is the formation of a monolayer that is resistant to native oxidation, as shown in block 308.

In an exemplary embodiment, the neutral species is halogen based and, more particularly, is fluorine based. The neutral species may be introduced using molecular fluorine (F₂) for example, or through a fluorine compound such as (but not limited to) CF₄, C₂F₆, SF₆, NF₃, and C₃F₈. Where a fluorine based species is used as the RIE etchant itself, the same may also be used as the neutral species after the RIE is completed. Alternatively, a different source for the neutral species (with respect to the reactive species) may be introduced into the RIE chamber. Finally, once the passivating monolayer is formed, the desired epitaxial growth is formed on the passivated surfaces of the substrate, as shown in block 310.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for preparing a substrate for epitaxial crystal growth thereon, the method comprising:
performing a reactive ion etch (RIE) on a selected area of the substrate to be prepared for epitaxial crystal growth;
discontinuing the introduction of an etchant species associated with the RIE; and
following said discontinuing the introduction of an etchant species, introducing a monolayer forming species into a chamber containing the substrate, said monolayer forming species selected so as to form a passivating monolayer on said selected area of the substrate, wherein said monolayer is resistant to the formation of oxide thereon.

2. The method of claim 1, wherein said discontinuing the introduction of an etchant species comprises deactivating a plasma excitation source of a reactive species.

3. The method of claim 1, wherein said monolayer forming species comprises a neutral species containing a halogen.

4. The method of claim 3, wherein said halogen comprises fluorine.

5. The method of claim 4, wherein said neutral species is introduced as molecular fluorine (F₂).

6. The method of claim 4, wherein said neutral species is introduced through a fluorine compound.

7. The method of claim 6, wherein said fluorine compound comprises one or more of: CF₄, C₂F₆, SF₆, NF₃, and C₃F₈.

8. The method of claim 2, wherein said monolayer forming species is generated from the same source as said etchant species used in said RIE, by said deactivating said plasma excitation source.

9. The method of claim 1, wherein said passivating monolayer is formed on said selected area of the substrate without implementing a precleaning operation of said selected area of the substrate following said RIE.

10. A method for forming a semiconductor device layer, the method comprising:
performing a reactive ion etch (RIE) on a selected area of a semiconductor substrate;
discontinuing the introduction of an etchant species associated with the RIE;
following said discontinuing the introduction of an etchant species, introducing a monolayer forming species into a chamber containing the substrate, said monolayer forming species selected so as to form a passivating monolayer on said selected area of the substrate, said monolayer resistant to the formation of oxide thereon; and
forming an epitaxially grown layer on said monolayer.

11. The method of claim 10, wherein said discontinuing the introduction of an etchant species comprises deactivating a plasma excitation source of a reactive species.

12. The method of claim 10, wherein said monolayer forming species comprises a neutral species containing a halogen.

13. The method of claim 12, wherein said neutral species comprises fluorine.

14. The method of claim 13, wherein said neutral species is introduced through molecular fluorine (F₂).

15. The method of claim 13, wherein said neutral species is introduced through a fluorine compound.

16. The method of claim 15, wherein said fluorine compound comprises one or more of: CF₄, C₂F₆, SF₆, NF₃, and C₃F₈.

17. The method of claim 11, wherein said monolayer forming species is generated from the same source as said etchant species used in said RIE, by said deactivating said plasma excitation source.

18. The method of claim 10, wherein said passivating monolayer is on said selected area of the substrate without implementing a precleaning operation of said selected area of the substrate following said RIE.

19. The method of claim 2, wherein said monolayer forming species is generated from a different source with respect to said etchant species used in said RIE.

20. The method of claim 11, wherein said monolayer forming species is generated from a different source with respect to said etchant species used in said RIE.
